(19) United States
(12) Patent Application Publication
(10) Pub. No.: US 2026/0194598 A1
(43) Pub. Date: Jul. 9, 2026

(54) INFORMATION PROCESSING DEVICE, INFORMATION PROCESSING METHOD, NON-TRANSITORY COMPUTER READABLE MEDIUM, AND INFORMATION PROCESSING SYSTEM

(71) Applicant: KABUSHIKI KAISHA TOSHIBA, Kawasaki-shi (JP)

(72) Inventors: Hisaaki HATANO, Yokohama (JP); Takahiro YAMAMOTO, Fuchu (JP); Kohei MARUCHI, Setagaya (JP); Kenji MITSUMOTO, Setagaya (JP)

(73) Assignee: KABUSHIKI KAISHA TOSHIBA, Kawasaki-shi (JP)

(21) Appl. No.: 19/558,032

(22) Filed: Mar. 5, 2026

Related U.S. Application Data
(63) Continuation of application No. PCT/JP2024/010572, filed on Mar. 18, 2024.

(51) Int. Cl. G01R 31/392; G01R 31/396

(52) U.S. Cl. CPC G01R 31/392; G01R 31/396

(57) ABSTRACT

According to one embodiment, an information processing device according to the present embodiment includes a processing circuitry that calculates target transition data representing a transition of a value of an index regarding a state of a target storage battery based on measurement data regarding the target storage battery, and estimates a timing at which a target event occurs in the target storage battery based on the target transition data and at least one piece of reference transition data representing a reference transition of the value of the index regarding a state of a storage battery in a period from a first time to a second time at which the target event occurs in the storage battery.

### CROSS REFERENCE TO RELATED APPLICATIONS

This application is a Continuation of International Application No. PCT/JP2024/010572, filed on March 18, 2024, the entire contents of which are incorporated herein by reference.

### FIELD

Embodiments described herein relate to an information processing device, an information processing method, a non-transitory computer readable medium, and an information processing system.

### BACKGROUND

Battery systems for an electric power system and battery systems operated as infrastructure such as public transportation are required to maintain performance and functions over a long period of time. The battery system is normally configured by connecting battery cells (also referred to as battery packs) in a series-parallel configuration serving as a minimum unit to constitute a battery module, connecting the battery modules in series in accordance with required voltages to constitute a battery unit, and connecting the battery units in parallel until the required battery capacity is obtained.

It is important to replace a battery unit at an appropriate time by estimating in advance a time at which the battery unit will stop due to partial deterioration of a battery system (for example, deterioration of the battery unit) and efficiently perform maintenance of the battery system. To implement this, it is necessary to estimate a time at which operation of the battery unit will stop (lifespans of some of the battery cells in the battery unit). A deductive method (such as simulation using a physical model, and an Arrhenius equation) based on electrochemistry for estimating a lifespan of a secondary battery is known for estimation of deterioration transition of a single battery cell. However, estimating lifespans of all the cells using measurement values of voltages for each cell requires cost to collect data in a large-scale battery system, and is not realistic.

In the battery unit, in many cases, instead of all the battery cells deteriorating at the same time, deterioration of some of the battery cells proceeds. In view of this, a technique has also been proposed for detecting deterioration of some of the battery cells in the battery unit using an index called a state of health (SoH) ratio. Calculation of the SoH ratio does not require measurement values of all the battery cells in the battery unit and requires less cost for collecting data because part of statistical data such as a maximum voltage, a minimum voltage, and an average voltage is used.

It is considered to estimate a timing (time) at which the battery unit will stop by estimating transition of the SoH ratio described above. However, the SoH ratio does not necessarily reflect deterioration of each of individual battery cells included in the battery unit, and thus, it is difficult to estimate transition of the SoH ratio.

### BRIEF DESCRIPTION OF THE DRAWINGS

FIG. 1 is a block diagram illustrating an example of an information processing device according to an embodiment of the present invention.

FIG. 2 is a view illustrating a configuration example of a storage battery system.

FIG. 3 is a view illustrating a configuration example of a battery module.

FIG. 4 is a view indicating an example of a deterioration model generated by a model generating unit.

FIG. 5 is a view indicating an example where a stop time of a target battery unit is estimated using the deterioration model.

FIG. 6 is a view indicating an example where the stop time of the target storage battery unit is estimated using a deterioration model different from the deterioration model in FIG. 5.

FIG. 7 is a view indicating an example where a maintenance plan is created using an estimated stop time of each battery unit.

FIG. 8 is a flowchart of an example of operation of the information processing device.

FIG. 9 is a view illustrating a hardware configuration of the information processing device.

### DETAILED DESCRIPTION

According to one embodiment, an information processing device comprising: a processing circuitry configured to: calculate target transition data representing a transition of a value of an index regarding a state of a target storage battery based on measurement data regarding the target storage battery; and estimate a timing at which a target event occurs in the target storage battery based on the target transition data and at least one piece of reference transition data representing a reference transition of the value of the index regarding a state of a storage battery in a period from a first time to a second time at which the target event occurs in the storage battery.

An embodiment of the present invention will be described below with reference to the drawings.

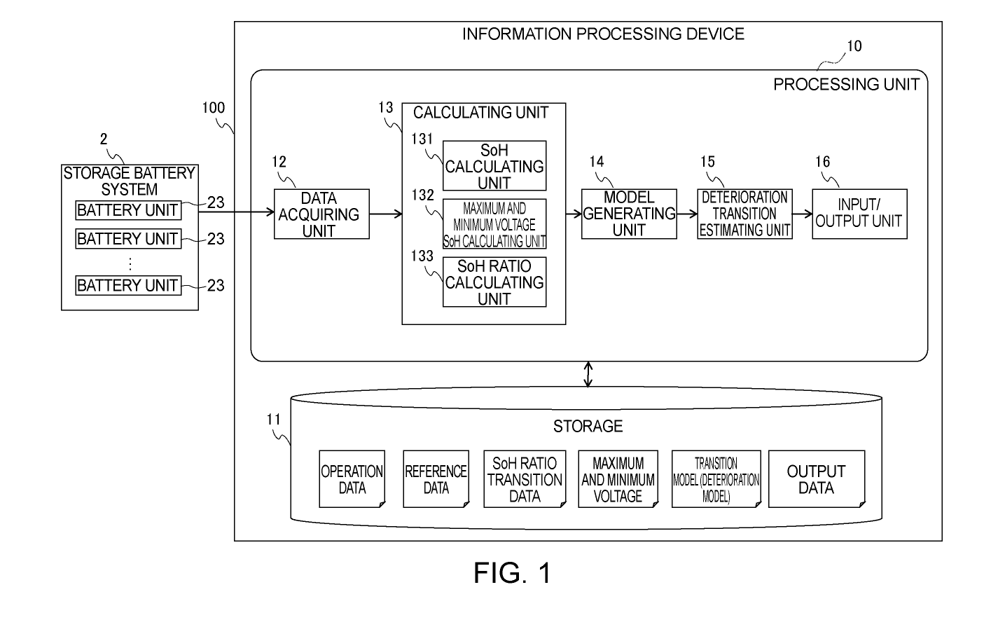

FIG. 1 is a block diagram illustrating an example of an information processing system 1 according to an embodiment of the present invention. The information processing system 1 includes a storage battery system 2, and an information processing device 100 according to the present embodiment. The information processing device 100 includes a processing unit 10 and a storage 11. The processing unit 10 includes a data acquiring unit 12, a calculating unit 13, a model generating unit 14, a deterioration transition estimating unit 15, and an input/output unit 16. The calculating unit 13 includes a state of health (SoH) calculating unit 131, a maximum and minimum voltage SoH calculating unit 132, and an SoH ratio calculating unit 133. The processing unit 10 may be configured as processing circuitry such as a CPU, an MPU, a GPU, a DSP, an ASIC, an FPGA, or a combination thereof.

The information processing device 100 is connected to the storage battery system 2 via a communication network. The communication network may be a wireless or wired network or may be a cable such as a serial bus cable. The input/output unit 16 has a function of outputting data or information to a user and accepting inputs of various kinds of information or an instruction from the user. As an example, the input/output unit 16 includes an output device such as a display device or a communication device, and an input device such as a keyboard, a mouse, and a voice input device. Further, the input/output unit 16 may be a touch panel also having an input/output function.

The storage battery system 2 includes a plurality of battery units, and the information processing device 100 is a device that estimates a timing at which a target event will occur for each battery unit among these battery units.

The target event is stopping of operation of the battery unit in the present embodiment. A case where the operation stops includes various cases such as a case where the operation stops due to a failure, and a case where the operation is stopped as a result of the user monitoring measurement data of the battery unit and determining that it is necessary to stop the operation. The target event can include various events such as an event in which a deterioration degree exceeds a threshold by a deterioration inspection, and an event in which the user determines that deterioration proceeds and sets the battery unit as a special monitored target.

Here, while the estimation includes both estimation with respect to a future time point and estimation with respect to a past time point, a case of estimation with respect to a future time point will be described in the following description. The estimation with respect to a future time point will be particularly referred to as prediction. The storage battery system 2 or the battery unit can be also referred to as a storage battery.

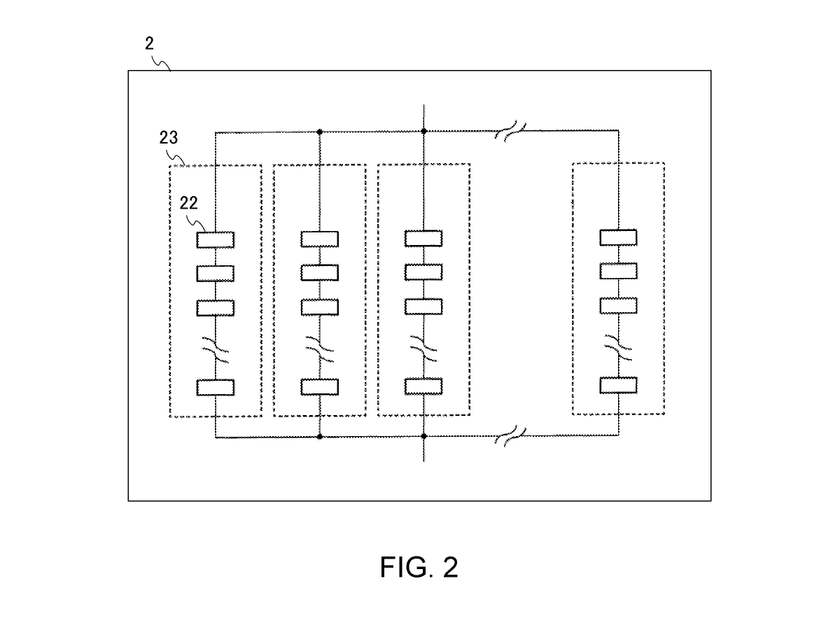

FIG. 2 illustrates a configuration example of the storage battery system 2. The storage battery system 2 has a configuration in which a plurality of battery units 23 is connected in parallel. Each battery unit 23 has a configuration in which a plurality of battery modules 22 is connected in series. Each battery unit 23 can be individually removed and can be replaced with a new battery unit.

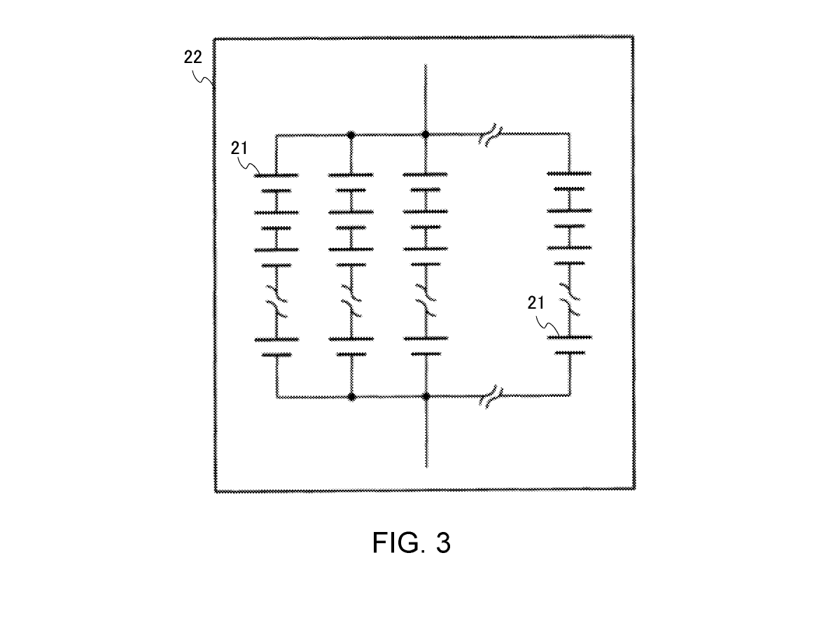

FIG. 3 illustrates a configuration example of the battery module 22. In the battery module 22, a plurality of unit batteries (cells) 21 is connected in series, and further, a plurality of series connections of the cells 21 is connected in parallel. As another configuration example of the battery module 22, a configuration including only one series connection of the cells 21 is also possible.

The configuration of the battery unit 23 in FIG. 2 is an example, and configurations other than the configuration in FIG. 2 may be employed. For example, the battery unit may include a series connection of a plurality of cells or include a plurality of series connections connected in parallel without including the battery modules.

While in the present embodiment, the battery unit 23 is set as a storage battery to be evaluated (target storage battery), the battery module 22 may be set as the target storage battery. Further, the storage battery system 2 may be set as the target storage battery. The target storage battery can be freely defined as long as it includes a plurality of cells. The battery unit 23 and the battery module 22 are an example of a storage battery capable of accumulating (charging) and discharging electric energy, and the target storage battery may employ other configurations as long as it includes a plurality of cells.

Parameters such as a voltage, a current, and a temperature of each battery unit 23 are measurable, and measured by measuring equipment and transmitted to the information processing device 100 as measurement data. For example, a battery management unit (BMU), a cell monitoring unit (CMU), or the like, included in a battery energy storage system (BESS) may record the parameters of each battery unit 23, or equipment capable of recording the parameters of the battery unit 23 may be separately provided within the storage battery system 2. Note that the measurement data may be directly transmitted to the information processing device 100 by the storage battery system 2 or the battery unit 23 or may be transmitted via a device, or the like, that collects information of the storage battery system 2 or information of the battery unit 23. As a result of the measurement data of each battery unit 23 of the operating storage battery system 2 being acquired in this manner, even if the storage battery system 2 is operating (for example, even if short-cycle charging and discharging are performed for 24 hours, every day), a timing (for example, a stop time) at which an event will occur in the battery unit 23 can be estimated. In this event, it is not necessary to stop the storage battery system 2 or the battery unit 23. The stop time of the battery unit may be estimated (in this case, estimated for the past time point) for the battery unit 23 for which the operation has already stopped.

It is assumed that the measurement data regarding each battery unit includes data necessary for calculating an SoH of at least the battery unit 2 (storage battery). The SoH is an index indicating a deterioration state that is an example of a state of the battery unit 2 (storage battery). Note that how the deterioration state of the battery unit 23 is represented may be determined as appropriate. For example, it is only necessary to define the deterioration state using a full charge capacity that decreases due to deterioration, internal resistance that increases due to deterioration, or the like.

In the present description, the SoH is defined using a ratio of a full charge capacity at the time point of evaluation with respect to a full charge capacity in the specification of the battery unit (a full charge capacity at the time point of evaluation/a full charge capacity in the specification). The time point of evaluation may be any time point. For example, in a case where the measurement data is stored every day as a file including a measurement result corresponding to one day, electric energy that has been dealt with in the day can be calculated from the measurement data corresponding to one day, and thus, the time point at which the measurement data is stored may be set as the time point of evaluation. Further, there can be a case where an SoH transition run chart that indicates electric energy on a horizontal axis and indicates an SoH on a vertical axis is generated based on the measurement result. In this case, an SoH for the cumulative number of equivalent cycles until reaching any time point of evaluation, or the like, may be calculated.

Any method may be used as a method for calculating the SoH of the battery unit 23. For example, a method is known in which a voltage of each battery unit (for example, an average voltage for each fixed period) is included in the measurement data, a standard deviation, a variance, or the like, of a distribution of the voltage values is calculated based on time-series data of the voltage, then, reference data indicating a general relationship between the standard deviation, the variance, or the like, of the distribution of the voltage values and the SoH is created from battery units (storage batteries) that have been deteriorated in various manners in advance, and the SoH is calculated from the calculated standard deviation or variance based on the reference data. It is only necessary to calculate the SoH using such a method. The reference data is stored in the storage 11 in advance.

Further, to calculate a maximum and minimum voltage SoH which will be described later, data indicating whether the battery unit 23 is performing charging or discharging is included in the measurement data. For example, in a case where a direction of a current charged/discharged to the battery unit 23 (storage battery) is represented by positive/negative of the current, the current charged/discharged to the storage battery is included in the measurement data. Further, a maximum value and a minimum value among the voltage values of the respective cells in the battery unit are included in the measurement data. The measurement data may include the maximum value and the minimum value among the voltage values of the battery modules included in the battery unit or may include a maximum voltage and a minimum voltage among a plurality of cells in the battery module for each battery module.

Note that values of the parameters not to be used for calculation of the SoH may be included in the measurement data.

The storage 11 stores data to be used for processing of the information processing device 100. Examples of the data can include, for example, measurement data (operation data) acquired from the storage battery system 2, reference data for calculating the SoH, SoH ratio transition data of each battery unit 23, SoH ratio transition data of the battery unit for which the operation has already stopped (past SoH ratio transition data), the deterioration model, and output data to be presented to the user. Details of these kinds of data will be described later. Note that the data stored in the storage 11 is not limited, and, for example, processing results, and the like, of respective components of the information processing device 100 may be stored.

The data acquiring unit 12 acquires the measurement data from the storage battery 2 or each battery unit 23 and accumulates the measurement data in the storage 11. The accumulated measurement data is used as history. For example, time-series data such as transition of the voltage of each battery unit can be confirmed from the accumulated measurement data.

The calculating unit 13 calculates an SoH ratio as an index for detecting deterioration (detecting deterioration acceleration) of any of the cells in the battery unit 23 based on the accumulated measurement data while setting each of the battery units 23 as the battery unit 23 to be evaluated. The calculating unit 13 includes an SoH calculating unit 131, a maximum and minimum voltage SoH calculating unit 132, and an SoH ratio calculating unit 133. While in the present embodiment, the SoH ratio is used as the index, other indexes may be used if a state of the battery unit including a plurality of cells can be evaluated.

The SoH calculating unit 131 calculates the SoH for the battery unit 23 based on the accumulated measurement data. For example, as described above, the SoH calculating unit 131 calculates the standard deviation or the variance of the distribution of the voltage values of the battery unit 23 per unit period such as one day. Then, the SoH calculating unit 131 calculates the SoH of the battery unit 23 from the calculated standard deviation or variance based on the reference data.

The maximum and minimum voltage SoH calculating unit 132 calculates a maximum and minimum voltage SoH for the battery unit 23 based on the accumulated measurement data. The maximum and minimum voltage SoH is an SoH based on the maximum voltage and the minimum voltage among the respective battery cells in the battery unit 23.

A difference in value of the internal resistance occurs in the cells included in the battery unit 23 due to deterioration. Thus, the voltages of the respective cells become different. The maximum and minimum voltage SoH calculating unit 132 treats the maximum voltage among the voltages of the respective cells as the voltage of the battery unit 23 at the time of charging and treats the minimum voltage among the voltages of the respective cells as the voltage of the battery unit 23 at the time of discharging. Then, in a similar manner to the SoH calculating unit 131, the maximum and minimum voltage SoH calculating unit 132 calculates the SoH of the battery unit 23. In other words, the maximum and minimum voltage SoH calculating unit 132 obtains maximum and minimum voltage data using the maximum voltage of the cells inside of the battery unit in place of the voltage of the battery unit at the time of charging of the battery unit 23, and the minimum voltage of the cells inside the battery unit in place of the voltage of the battery unit 23 at the time of discharging of the battery unit 23. Then, the maximum and minimum voltage SoH calculating unit 132 calculates the SoH of the battery unit 23 from the maximum and minimum voltage data and sets the calculated SoH as the maximum and minimum voltage SoH.

The cell for which the voltage becomes the maximum voltage at the time of charging of the battery unit 23 does not necessarily match the cell for which the voltage becomes the minimum voltage at the time of discharging of the battery unit 23, and the cells temporarily indicate the most deteriorated state among the cells within the battery unit. In other words, the maximum and minimum voltage SoH indicates a possibility of a state in which deterioration proceeds most within the battery unit 23 and thus becomes a value smaller than the SoH.

For example, a voltage standard deviation method capable of evaluating the SoH without stopping the storage battery that is performing charging/discharging is known. In the voltage standard deviation method, a trajectory diagram of plots in which a state of charge (SoC) of the cell that is performing charging/discharging is indicated on an X coordinate, and a terminal voltage of the cell is indicated on a Y coordinate, is used. It is known that a distribution of the plots in a Y axis direction, in other words, variation in terminal voltage expands in accordance with decrease of the SoH even with the same charging/discharging power. In the voltage standard deviation method, the SoH is estimated based on the distribution. In a case where the maximum and minimum voltage SoH is calculated using this voltage standard deviation method, a plot with the maximum voltage on the Y coordinate and the plot with the minimum voltage on the Y coordinate are indicated in the trajectory diagram. Thus, the distribution in the Y axis direction becomes extremely large. It can be seen also from this that the maximum and minimum voltage SoH becomes a value smaller than the SoH.

The SoH ratio calculating unit 133 calculates the SoH ratio for each battery unit 23. The SoH ratio represents a ratio of the maximum and minimum voltage SoH of the battery unit 23 with respect to the SoH of the battery unit 23 (the maximum and minimum voltage SoH/SoH). As described above, the maximum and minimum voltage SoH depends on a state in which the deterioration proceeds most in the battery unit. On the other hand, the SoH depends on all the cells within the battery unit 23. Thus, in a case where the state in which the deterioration proceeds most is substantially the same as states of other cells, the SoH ratio becomes a value close to 1, and in a case where a difference between the state in which the deterioration proceeds most and the states of other cells is large, the SoH ratio becomes a value smaller than 1. In other words, the SoH ratio represents how much deterioration proceeds in the state where the deterioration proceeds most in the battery unit compared to the states of other cells. By using the SoH ratio as the index, it is possible to recognize that even if the whole of the battery unit 23 looks healthy, deterioration proceeds more in some of the cells in the battery unit 23 than other cells.

Every time the SoH ratio is calculated by the SoH ratio calculating unit 133, the SoH ratio is stored in the storage 11 in association with identification information of the battery unit 23 for which the SoH ratio is calculated. Time series (aggregate) of the SoH ratio calculated for the same battery unit 23 will be referred to as SoH ratio transition data. The SoH ratio transition data includes a time series of SoH ratios for each of a plurality of times (third times) and represents an SoH ratio transition. In a case where the calculating unit 13 calculates the SoH ratio once a day, the SoH ratio transition data is updated by the SoH ratio being added once every day. In a case where the battery system 2 includes X battery units 23, X pieces of SoH ratio transition data are stored so as to correspond to these X battery units 23 and are updated daily. Note that the time in the present embodiment may be measured either in seconds, in minutes, in hours, or in days. It is assumed in the following description that the time is measured in days.

Further, the SoH ratio transition data (hereinafter, referred to as past SoH ratio transition data) for a plurality of battery units that has already stopped in the past (for example, the lifespans have ended or the battery units have been replaced) is stored in the storage 11 (see FIG. 1). The SoH ratio transition data may be generated by the calculating unit 13 or may be provided in advance from the outside. The plurality of battery units is different from a plurality of battery units 23 in the operating storage battery system 2 and has already stopped operation. These battery units that have stopped operation in the past will be also referred to as "past battery units".

Data at the end of the past SoH ratio transition data corresponds to a time (stop time) at which the operation has been stopped.

The model generating unit 14 extracts data of a length equal to or longer than a fixed period, dated back from data at the time of the end of the SoH ratio transition data of a plurality of past battery units. The fixed period by which the data is dated back may be equal to or longer than one year such as one year, one and half year, and two years, or may be less than one year. The extracted SoH ratio transition data is described as the extracted SoH ratio transition data.

The model generating unit 14 maps the plurality of pieces of SoH ratio transition data in a space defined by time on the horizontal axis and indicating an SoH ratio on a vertical axis, aligns the data at the end of the data to a position of the same time and clusters these pieces of the extracted SoH ratio transition data. Any method such as hierarchical clustering or non-hierarchical clustering can be used in the clustering. By this means, one or a plurality of clusters are generated. While a case will be assumed where there is a plurality of the clusters, the number of the clusters may be one.

The model generating unit 14 averages the extracted SoH ratio transition data belonging to the cluster with the time corresponding to each other (the same time in a state where the above-described alignment is performed) for each cluster and obtains a sequence of the averaged values as reference SoH ratio transition data (reference time-series data). An aggregate of the reference SoH ratio transition data obtained for each cluster will be referred to as a transition model (or a deterioration model). While only one deterioration model is generated here, a plurality of deterioration models may be generated by changing the above-described fixed period by which the data is dated back. The deterioration model generated by the model generating unit 14 is stored in the storage 11 (see FIG. 1).

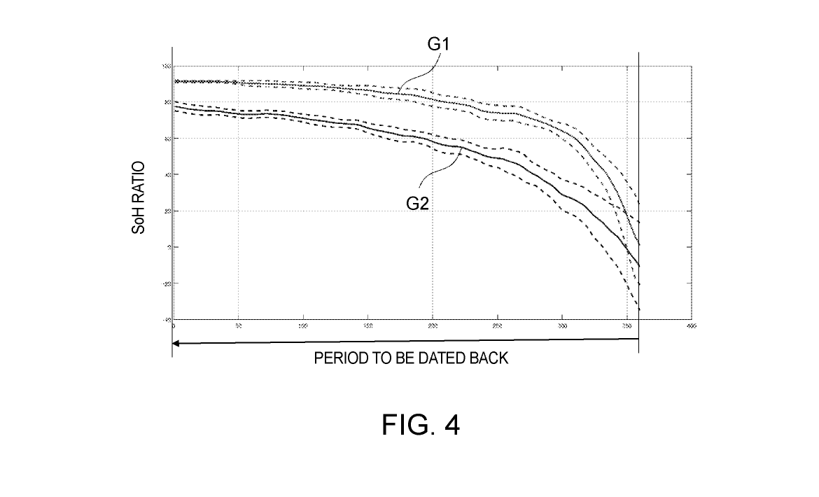

FIG. 4 indicates an example of the deterioration model generated by the model generating unit 14. Two pieces of reference SoH ratio transition data G1, G2 are respectively indicated as graphs. The two pieces of the reference SoH ratio transition data G1, G2 will be also described as reference graphs G1, G2. Two broken lines sandwiching the reference SoH ratio transition data G1 represent the standard deviation lines. In a similar manner, two broken lines sandwiching the reference SoH ratio transition data G2 represents the standard deviation. The ends of the reference SoH ratio transition data G1, G2 are made the same, and a size of the reference SoH ratio transition data G1, G2 corresponds to the length of the period by which the data is dated back described above. Note that while actual times of the ends of the reference SoH ratio transition data G1, G2 (times at which the battery units have actually stopped) may be different from each other, positions of the data at both ends are aligned at the same position in the space for alignment. The time indicated by each of the data at the actual ends of the reference SoH ratio transition data G1, G2 corresponds to a second time, and the time dating back from the time of the end by the above-described period corresponds to a first time. The first time and the second time may be different for each of the reference SoH ratio transition data G1, G2.

The deterioration transition estimating unit 15 reads the SoH ratio transition data of the target battery unit from the storage 11 while setting each battery unit 23 as the target battery unit (target storage battery) and estimates a timing at which a target event will occur in the target battery unit using the read SoH ratio transition data and the deterioration model described above. Specifically, the deterioration transition estimating unit 15 estimates a timing (for example, a time) at which the target battery unit will stop in the present example. The time to be estimated here is a time after the latest time at which the SoH ratio is calculated for the target battery unit.

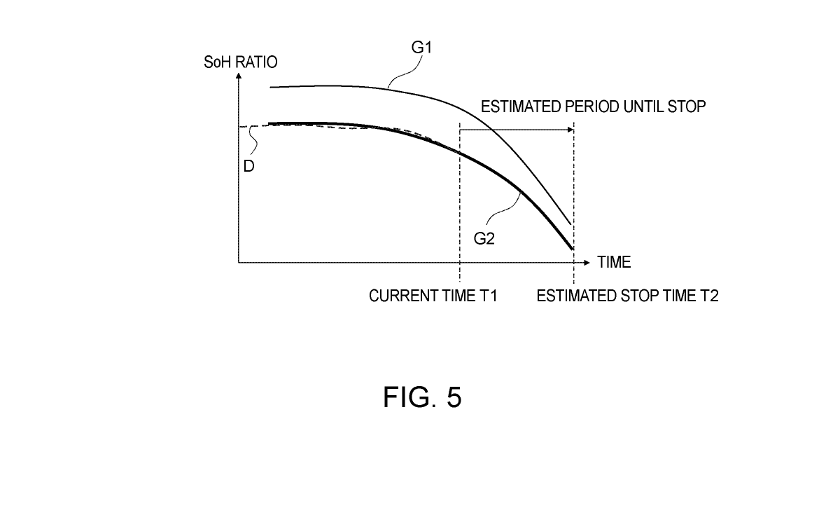

FIG. 5 indicates an example where the stop time of the target battery unit is estimated using the deterioration model. SoH ratio transition data D of the target battery unit is indicated with a solid line in the graph. The SoH ratio transition data D will be also described as a target graph D. Further, the reference SoH ratio transition data G1, G2 (reference graphs G1, G2) in the deterioration model is indicated. While the reference SoH ratio transition data G1, G2 is similar to that in FIG. 4, the reference SoH ratio transition data G1, G2 is displayed more simply than that in FIG. 5. The SoH ratio transition data D and the reference SoH ratio transition data G1, G2 are laid out in a space indicating time on a horizontal axis and indicating an index (the SoH ratio in the present example) on a vertical axis.

The deterioration transition estimating unit 15 calculates a matching degree (also referred to as similarity) based on a distance from the reference graphs G1, G2 while moving the SoH ratio transition data D (target graph D) and at least one of the reference graphs G1, G2 in a horizontal direction (time direction). A higher matching degree (similarity) means a closer distance. Note that when the matching degree is calculated, it is not necessary to make the positions of the ends of the reference graphs G1, G2 the same, and the relative positions with the target graph D are independently adjusted in the time direction. A reference graph (reference SoH ratio transition data) that most matches the target graph D and a position at which the reference graph matches the target graph D are searched for based on the matching degree. In the example in FIG. 5, the target graph D most matches the reference graph G2 at the position in the figure. A period corresponding to a distance in the time direction from the time (referred to as a current time T1) indicated by the data at the end of the target graph D (SoH ratio transition data D) at the position at which target graph D most matches the reference graph G2 to the position of the end of the reference graph G2 is calculated as an estimation period EP until the target battery unit will stop. Further, by adding the estimation period EP to the current time T1, a time (estimated stop time T2) at which the target battery unit is estimated to stop is obtained. The estimated stop time T2 is an example of a timing at which a target event is estimated to occur in the target battery unit.

In the calculation of the matching degree here, for example, a distance between two pieces of data (here, a distance between the target graph D and the reference graph G1 or G2) at the time (the same time) corresponding to each other in the space is calculated at a plurality of times (for example, all times) corresponding to each other, and a value of a sum of the calculated distances is divided by the number of the plurality of times. The distance is, for example, a Euclidean distance, but is not limited to this. By dividing the value of the sum of the distances by the number of times, even in a case where the number of times (the number of samples) corresponding to each other is different for each reference graph (reference SoH transition data) for which the matching degree is to be calculated, appropriate evaluation can be performed.

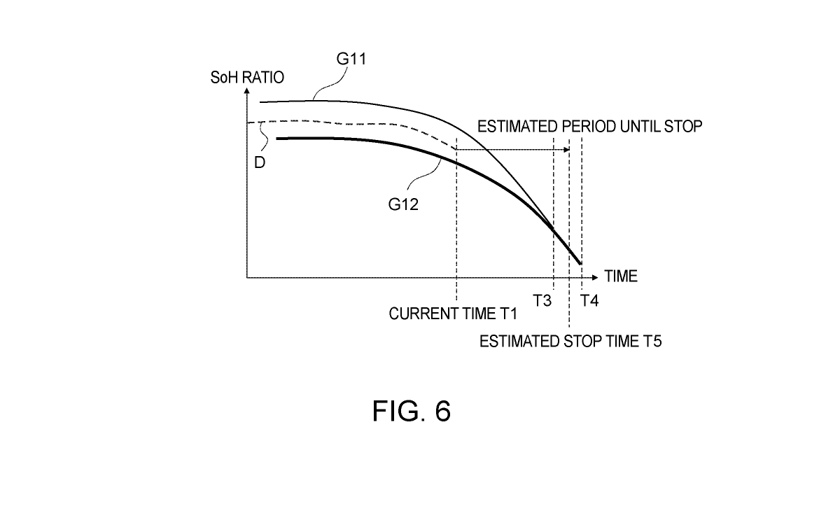

FIG. 6 indicates an example where the stop time of the target battery unit is estimated using a deterioration model different from that in FIG. 5. Here, reference SoH ratio transition data G11, G12 (reference graphs G11, G12) different from those in FIG. 5 are indicated. It is assumed that the SoH ratio transition data D (target graph D) is the same as that in FIG. 5.

A case is indicated where both the reference graphs G11, G12 match the target graph D with the matching degree equal to or higher than a threshold. The reference graphs G11, G12 most match the target graph D respectively at positions in the figure, and the matching degree is higher than the threshold at both positions.

In this case, for example, a point obtained by internally dividing an interval between a stop time T3 of the target battery unit estimated from the reference graph G11 and a stop time T4 of the target battery unit estimated from the reference graph G12 in accordance with a distance (matching degree) from the reference graph G11 and a distance (matching degree) from the reference graph G12 is set as an estimated stop time T5. In other words, a ratio of the matching degree between the reference graph G11 and the reference graph G12 is calculated, a weighted sum of a period until the stop time T3 and a period until the stop time T4 is calculated based on the ratio, and a value of the weighted sum (period) is added to the time of the end of the target graph D, thereby the estimated stop time T5 can be obtained. While in the example in FIG. 6, two reference graphs are used as reference graphs with high matching degrees, the estimated stop time can be obtained by performing similar weighted calculation using three or more reference graphs with high matching degrees.

As another method, a reference graph for which a period from the end of the target graph D to the end of the reference graph is the shortest among the reference graphs with matching degrees equal to or higher than the threshold may be selected. A period corresponding to a distance in the time direction from data at the end of the target graph D to the end of the selected reference graph is calculated as an estimated period until the target battery unit will stop. The time obtained by adding this estimated period to the time (current time) indicated by the data at the end of the target graph D is calculated as the time (estimated stop time) at which the target battery unit is estimated to stop.

While in the example in FIG. 5 described above, one of the reference graphs (reference SoH ratio transition data) is selected using each reference graph and the matching degrees, the reference graph may be selected using other methods. For example, the calculating unit 13 calculates as attribute information, a temporal change or an integrated value of at least one of a temperature, a current value, a voltage value, a power value, or an SoC until the storage battery unit has stopped in the past in association with the past SoH ratio transition data. When the model generating unit 14 generates the reference SoH ratio transition data from the past SoH ratio transition data belonging to the cluster, the model generating unit 14 obtains the attribute information of the reference SoH ratio transition data through averaging, or the like, of the attribute information. Attribute information including the same items as described above is also generated for the target battery unit. The deterioration transition estimating unit 15 compares the attribute information for the target battery unit including the same items as described above with the attribute information of a plurality of pieces of reference SoH ratio transition data to select the reference SoH ratio transition data with the closest values. The stop time is estimated using the selected reference SoH ratio transition data. The stop time may be estimated by applying the present method to the example in FIG. 6 and selecting two or a plurality of pieces of reference SoH ratio transition data with the closest values.

In a case where there is no reference graph with a matching degree equal to or higher than the threshold, the estimated stop time of the target battery unit is not calculated, and the estimated stop times calculated for other battery units 23 (except battery units for which the estimated stop times have not been calculated among the other battery units) in the storage battery system 2 are acquired. The latest time among the acquired estimated stop times is set as Tmax. It may be determined that the above-described target battery unit will not stop until the time Tmax. Alternatively, a period from the current time to Tmax may be calculated, and it may be determined that the target battery unit will not stop during the calculated period. In a case where the estimated stop times are not calculated for all the battery units 23 in the storage battery system 2, it may be determined that the target battery unit will not stop during a period from the current time to a time T0 determined in advance. A length of the period until the time T0 may be, for example, set at a data length (see FIG. 4) extracted from the past SoH ratio transition data used to generate the deterioration model. In other words, the length may be set at a length of a period by which the data is dated back from the time indicated by the data at the end of the past SoH ratio transition data.

The input/output unit 16 generates output data including information regarding the stop time estimated by the deterioration transition estimating unit 15 in association with identification information of the battery unit 23 to be estimated and outputs the output data to the user in a visible manner. In a case where estimation is performed for all the battery units 23 in the storage battery system 2, the input/output unit 16 may output the output data including the information regarding the stop times for all the battery units 23 after executing estimation for all the battery units 23. The user who views the output data displayed at the input/output unit 16 (display device) can determine whether there is a battery unit 23 for which the lifespan will end (stop time is approaching) and can determine to perform maintenance work (replacement) of the battery unit 23 for which a period until the stop time is short.

### Regeneration of Deterioration Model

In the example in FIG. 5, there can be a case where the target battery unit stops before elapse of the estimated period until the target battery unit stops, calculated for the target battery unit (a case where the battery unit stops earlier than estimated). In this case, the processing unit 10 receives information indicating that the target battery unit has stopped before elapse of the estimated period via the input/output unit 16 and stores the SoH ratio transition data until the target battery unit stops in the storage 11 as new past SoH ratio transition data. Note that a case where the battery unit stops includes various cases such as a case where the operation is stopped due to a failure, and a case where the operation is stopped as a result of the user monitoring measurement data of the target battery unit and determining that it is necessary to stop the operation. Further, the model generating unit 14 regenerates the deterioration model additionally using the new past SoH ratio transition data. This can improve accuracy of the deterioration model.

Further, there can be also a case where the battery unit continues to operate even if the target battery unit is left as is without being replaced after the estimated stop time elapses, and a period until the battery unit actually stops is longer than the estimated period. Also in this case, after the target battery unit has actually stopped, the deterioration model may be regenerated in a similar manner to a case where the battery unit has stopped earlier than estimated as described above using the SoH ratio transition data until the target battery unit stops as new past SoH ratio transition data.

### Creation of Maintenance Plan

The input/output unit 16 may create a maintenance plan as output data based on information regarding the stop time estimated by the deterioration transition estimating unit 15 and output the information of the maintenance plan to the user.

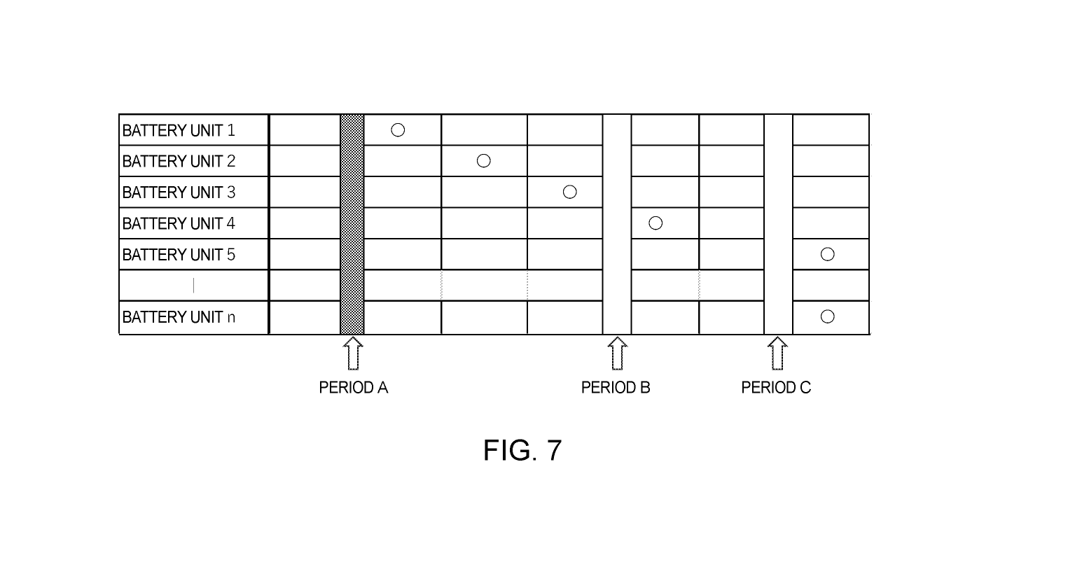

FIG. 7 indicates an example where the maintenance plan is created using the estimated stop time of each battery unit 23. There are n battery units for which the stop times are estimated, and information of the battery units is arranged in ascending order of a period until the battery unit stops in a longitudinal direction from the above. A battery unit x represents a battery unit for which a period until the battery unit stops is the x-th shortest. The right direction represents the time direction. To facilitate understanding, a lateral direction is separated into periods at a fixed time interval. in the figure schematically indicates a period including the estimated stop time of the battery unit. Periods A, B, C are candidate periods for performing maintenance work (such as replacement).

To prevent the operating unit from stopping while the battery unit is operating, it is necessary to replace the battery unit before the estimated stop time. Thus, if replacement is not performed for the battery units 1 to 3 in the next period A, the replacement cannot be performed before the estimated stop times, and thus, the battery units 1 to 3 have to be replaced in the period A. In this event, whether or not to replace the battery units 4 to n at the time point of the period A is changed according to whether the next replacement period is the period B, the period C or further future period.

If the maintenance work of the next next time can be performed in the period B, it is only necessary to replace only the battery units 1, 2, 3 in the period A. On the other hand, if the maintenance work of the next next time is performed in the period C, it is necessary to replace also the battery unit 4 in the maintenance work in the period A. If the maintenance work of the next next time is performed in further future after the period C, it is necessary to replace all the units of the battery units 1 to n at the time point of the period A.

It is therefore possible to determine the battery units to be replaced in a case where the periods of the maintenance work are determined using the estimated stop times. Further, it is possible to determine the periods of the maintenance work in a case where the number of battery units to be replaced is determined using the estimated stop times. Such determination may be performed by the processing unit 10 or the input/output unit 16, and the determined result may be output from the input/output unit 16 to the user as maintenance plan related data.

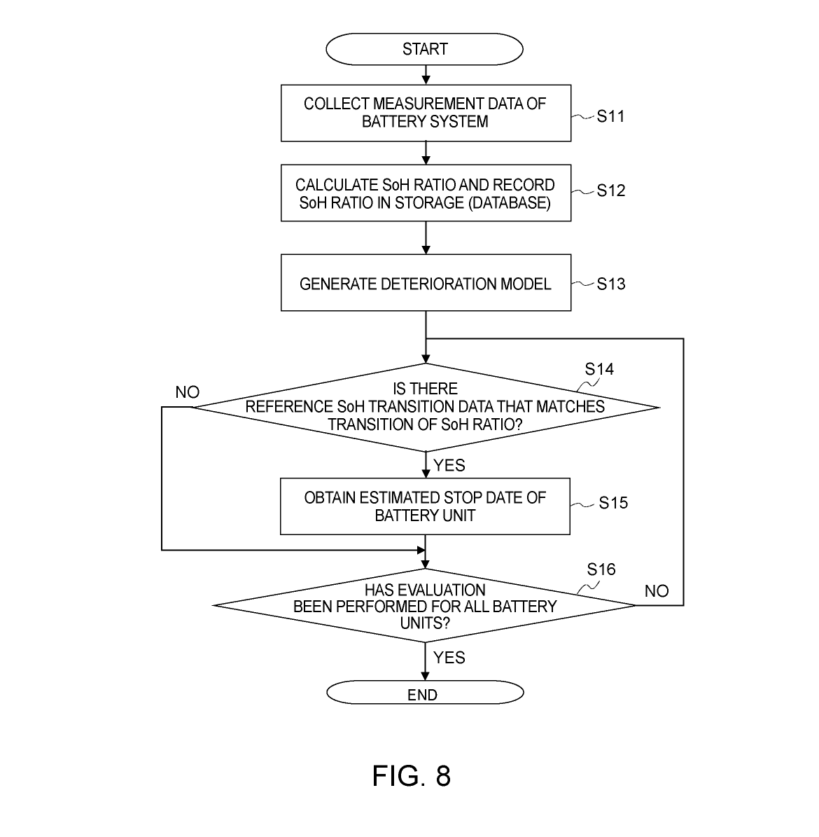

FIG. 8 is a flowchart of an example of operation of the information processing device 100. Here, description will be provided assuming a case where the method described above in FIG. 5 is performed as operation of the deterioration transition estimating unit 15.

The data acquiring unit 12 acquires measurement data (operation data) of each battery unit 23 from the storage battery system 2 and stores the measurement data in the storage 11 (S11), and the calculating unit 13 calculates an SoH ratio using the acquired measurement data and stores the SoH ratio in the storage 11 (S12). In other words, the SoH ratio transition data is updated by adding the SoH ratio calculated this time to the SoH ratio transition data for each battery unit 23. The model generating unit 14 generates a deterioration model (transition model) based on the past SoH ratio transition data (S13). However, in a case where the deterioration model has already been generated and stored in the storage 11, in a case where generation conditions of the deterioration model are not satisfied, the deterioration model does not have to be generated. An example where the generation conditions are satisfied can include, for example, a case where new past SoH ratio transition data is added after the deterioration model is generated last time. Alternatively, it may be determined that the generation conditions are satisfied in a case where a generation instruction of the deterioration model is explicitly provided from the user.

The deterioration transition estimating unit 15 calculates a matching degree between the SoH transition data of the battery unit 23 and each piece of reference SoH transition data included in the deterioration model and detects the matched reference SoH transition data and a position at which the SoH transition data matches the reference SoH transition data (S14). For example, the deterioration transition estimating unit 15 detects the reference SoH transition data with the matching degree equal to or higher than the threshold and with the highest matching degree, and a position at which the SoH transition data most matches the reference SoH transition data (the matching degree is the highest or a distance is close), that is, a relative position between the most matched reference SoH transition data and the SoH transition data. When the matched reference SoH transition data is detected (S14: Yes), the deterioration transition estimating unit 15 calculates a period corresponding to a distance in the time direction from the end of the SoH transition data to the end of the matched reference SoH transition data at the position at which the SoH transition data matches the reference SoH transition data, as an estimated period until the operation will be stopped. The deterioration transition estimating unit 15 calculates the time indicated by the data at the end of the SoH transition data (time obtained by adding the estimated period to the current time) as the estimated stop time (for example, the estimated stop date) of the battery unit (S15). Then, it is determined whether evaluation has been performed for all the battery units (S16). Also in a case where the matched reference SoH transition data is not detected in step S14 described above (S14: No), it is determined whether evaluation has been performed for all the battery units (S16).

In a case where there is a battery unit for which evaluation has not been performed (S16: No), the processing returns to step S14. In a case where evaluation has been performed for all the battery units (S16: Yes), the present processing ends.

As described above, according to the present embodiment, it is possible to estimate the number of days until the battery unit will stop even without operation data (measurement data) of all the cells in the storage battery (battery unit) and determine an appropriate time for maintenance work.

### Hardware configuration

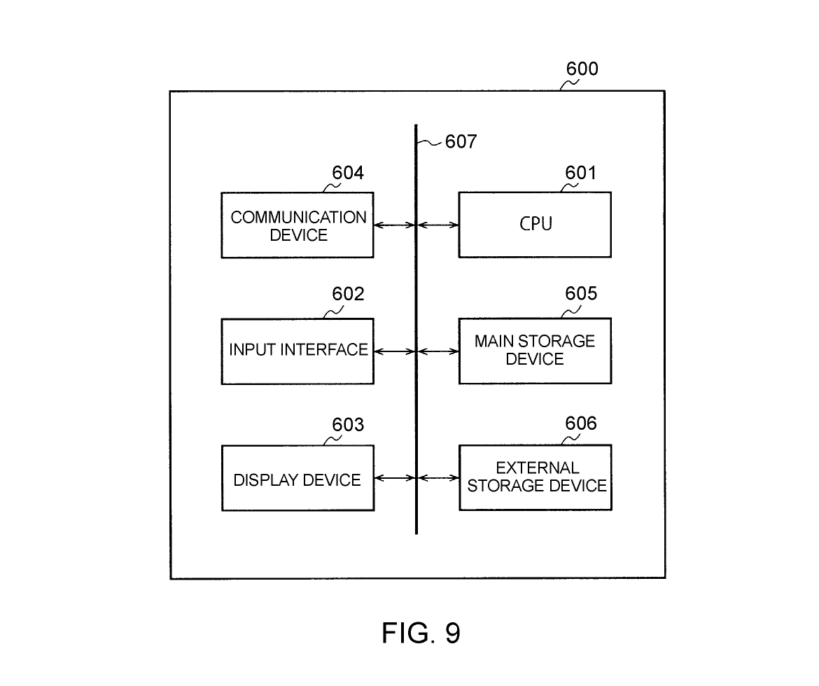

FIG. 9 illustrates a hardware configuration of the information processing device according to each embodiment. The information processing device is configured as a computer device 600. The computer device 600 includes a CPU 601, an input interface 602, a display device 603, a communication device 604, a main storage device 605, and an external storage device 606, and these components are mutually connected through a bus 607.

The CPU (central processing unit) 601 executes an information processing program as a computer program on the main storage device 605. The information processing program is a computer program configured to achieve each above-described functional composition of the present device. The information processing program may be achieved by a combination of a plurality of computer programs and scripts instead of one computer program. Each functional composition is achieved as the CPU 601 executes the information processing program.

The input interface 602 is a circuit for inputting, to the present device, an operation signal from an input device such as a keyboard, a mouse, or a touch panel. The input interface 602 corresponds to the input/output unit 16.

The display device 603 displays data output from the present device. The display device 603 is, for example, a liquid crystal display (LCD), an organic electroluminescence display, a cathode-ray tube (CRT), or a plasma display (PDP) but is not limited thereto. Data output from the computer device 600 can be displayed on the display device 603. The display device 603 corresponds to the output device in each embodiment. The display device 603 corresponds to the input/output unit 16.

The communication device 604 is a circuit for the present device to communicate with an external device in a wireless or wired manner. Data can be input from the external device through the communication device 604. The data input from the external device can be stored in the main storage device 605 or the external storage device 606. The communication device 604 corresponds to the input/output unit 16.

The main storage device 605 stores, for example, the information processing program, data necessary for execution of the information processing program, and data generated through execution of the information processing program. The information processing program is loaded and executed on the main storage device 605. The main storage device 605 is, for example, a RAM, a DRAM, or an SRAM but is not limited thereto. Each storage or database in the information processing device 100 may be implemented on the main storage device 605.

The external storage device 606 stores, for example, the information processing program, data necessary for execution of the information processing program, and data generated through execution of the information processing program. The information processing program and the data are read onto the main storage device 605 at execution of the information processing program. The external storage device 606 is, for example, a hard disk, an optical disk, a flash memory, or a magnetic tape but is not limited thereto. Each storage or database in the information processing device 100 may be implemented on the external storage device 606.

The information processing program may be installed on the computer device 600 in advance or may be stored in a non-transitory computer readable medium or a storage medium such as a CD-ROM. Moreover, the information processing program in each embodiment may be uploaded on the Internet.

The present device may be configured as a single computer device 600 or may be configured as a system including a plurality of mutually connected computer devices 600.

Note that the present invention is not limited to the above-described embodiments as they are, and can be embodied by modifying the constituent elements without departing from the gist thereof in the implementation stage. In addition, various inventions can be formed by appropriately combining a plurality of constituent elements disclosed in the above-described embodiments. For example, a configuration in which some constituent elements are deleted from all the constituent elements shown in the embodiments is also conceivable. Furthermore, the constituent elements described in different embodiments may be appropriately combined.

The embodiments as described before may be configured as below.

Clause 1 An information processing device comprising: a processing circuitry configured to:

calculate target transition data representing a transition of a value of an index regarding a state of a target storage battery based on measurement data regarding the target storage battery; and

estimate a timing at which a target event occurs in the target storage battery based on the target transition data and at least one piece of reference transition data representing a reference transition of the value of the index regarding a state of a storage battery in a period from a first time to a second time at which the target event occurs in the storage battery.

Clause 2 The information processing device according to clause 1, wherein

the target storage battery has a plurality of cells, and the processing circuitry calculates the value of the index based on a minimum voltage and a maximum voltage among voltages of the plurality of cells in the target storage battery for each of a plurality of third times, and calculates data including the values of the index at the plurality of third times as the target transition data. Clause 3 The information processing device according to clause 1 or 2, wherein the processing circuitry

calculates transition data representing a transition of the value of the index regarding states of a plurality of storage batteries until the target event occurs in the plurality of storage batteries based on measurement data regarding the plurality of storage batteries in which the target event has occurred;

generates at least one cluster each including one or more pieces of the transition data by clustering a plurality of pieces of the transition data calculated for the plurality of storage batteries; and generates the reference transition data for each of the clusters based on the one or more pieces of the transition data included in the cluster.

Clause 4 The information processing device according to any one of clauses 1 to 3, wherein the processing circuitry:

maps the target transition data and a plurality of pieces of the reference transition data in a space defined by time and the index;

selects one piece of the reference transition data based on a distance between the target transition data and the plurality of pieces of the reference transition data by moving at least one of the target transition data or the plurality of pieces of the reference transition data in a time direction, and aligns the one piece of the reference transition data with the target transition data;

calculates a distance in the time direction from an end of the target transition data to an end of the one piece of the reference transition data; and

estimates the timing at which the target event occurs by adding a time corresponding to the calculated distance in the time direction to a time indicated by data at the end of the target transition data.

Clause 5 The information processing device according to any one of clauses 1 to 4, wherein the processing circuitry:

maps the target transition data and a plurality of pieces of the reference transition data in a space defined by time and the index;

selects two or more pieces of the reference transition data for the target transition data based on a distance between the target transition data and the plurality of pieces of the reference transition data by moving at least one of the target transition data or the plurality of pieces of the reference transition data in a time direction, and aligns the selected two or more pieces of the reference transition data with the target transition data;

calculates a plurality of distances in the time direction from an end of the target transition data to ends of the two or more pieces of the reference transition data; and estimates the timing at which the target event occurs based on times corresponding to the calculated plurality of distances in the time direction, a ratio between the distances associated with the respective two or more pieces of the reference transition data, and a time indicated by data at the end of the target transition data.

Clause 6 The information processing device according to any one of clauses 1 to 5, wherein attribute information indicating a temporal change or an accumulated value of at least one of temperature, a current value, a voltage value, a power value, and an SoC is associated with each of a plurality of pieces of the reference transition data, and the processing circuitry:

calculates attribute information indicating a temporal change or an accumulated value of at least one of temperature, a current value, a voltage value, a power value, and an SoC based on the measurement data regarding the target storage battery; and selects at least one piece of the reference transition data based on the calculated attribute information and a plurality of pieces of the attribute information associated with the plurality of pieces of the reference transition data, and estimates the timing at which the target event occurs based on the selected reference transition data and the target transition data.

Clause 7 The information processing device according to any one of clauses 1 to 6, wherein the processing circuitry acquires information indicating a timing at which the target event occurred in the target storage battery, and when a difference between the timing indicated by the acquired information and the estimated timing at which the target event occurs satisfies a condition, generates the reference transition data based on transition data of the value of the index of the target storage battery until the target event occurs.

Clause 8 The information processing device according to any one of clauses 1 to 7, wherein the target event is stopping of operation, and the timing at which the target event occurs in the target storage battery is a time at which operation of the target storage battery stops.

Clause 9 The information processing device according to clause 8, wherein the time at which operation of the target storage battery stops is a date on which operation of the target storage battery stops.

Clause 10 The information processing device according to any one of clauses 1 to 9, wherein the target storage battery has a plurality of cells, and the processing circuitry calculates a first SoH based on the measurement data of the target storage battery, calculates a second SoH based on a minimum voltage and a maximum voltage among voltages of the plurality of cells in the target storage battery, and calculates the value of the index using a ratio between the second SoH and the first SoH.

Clause 11 The information processing device according to clause 4, wherein the processing circuitry selects the reference transition data having a similarity according to the distance that is equal to or higher than a threshold and having the highest similarity, and when the reference transition data having the similarity equal to or higher than the threshold does not exist, estimates that the timing at which the target event occurs is after a time obtained by adding a length of the period from the first time to the second time to a time indicated by data at the end of the target transition data.

Clause 12 The information processing device according to clause 4, wherein the processing circuitry selects the reference transition data having a similarity according to the distance that is equal to or higher than a threshold and having the highest similarity, the processing circuitry estimates the timing at which the target event occurs for a plurality of the target storage batteries, and when there is a target storage battery for which the reference transition data having the similarity equal to or higher than the threshold does not exist, the processing circuitry sets, as the timing at which the target event occurs, a time obtained by adding a time period until a latest timing among timings estimated for one or more of the target storage batteries for which the reference transition data having the similarity equal to or higher than the threshold exists, to a time indicated by data at the end of the target transition data of the target storage battery for which the reference transition data having the similarity equal to or higher than the threshold does not exist.

Clause 13 The information processing device according to clause 1, wherein the processing circuitry calculates a similarity based on a distance between the target transition data and a plurality of pieces of the reference transition data, selects the reference transition data having the largest similarity, and aligns the reference transition data with the target transition data at a position where the similarity becomes largest.

Clause 14 The information processing device according to clause 5, wherein the processing circuitry calculates a similarity based on a distance between the target transition data and a plurality of pieces of the reference transition data, selects two or more pieces of the reference transition data having the largest similarity, and aligns each of the two or more pieces of the reference transition data with the target transition data at a position where the similarity becomes largest.

Clause 15 The information processing device according to any one of clauses 1 to 14, wherein the processing circuitry: maps the target transition data and the reference transition data in a space defined by time and the index; aligns the reference transition data with the target transition data at a position where a similarity according to a distance between the target transition data and the reference transition data becomes highest or becomes equal to or higher than a threshold by moving at least one of the target transition data or the reference transition data in a time direction; calculates a distance in the time direction from an end of the target transition data to an end of one piece of the reference transition data; and estimates the timing at which the target event occurs by adding a time corresponding to the calculated distance in the time direction to a time indicated by data at the end of the target transition data.

Clause 16 An information processing method comprising:

calculating target transition data representing a transition of a value of an index regarding a state of a target storage battery based on measurement data regarding the target storage battery; and estimating a timing at which a target event occurs in the target storage battery based on the target transition data and at least one piece of reference transition data representing a reference transition of the value of the index regarding a state of a storage battery in a period from a first time to a second time at which the target event occurs in the storage battery.

Clause 17 A computer program for causing a computer to execute:

a step of calculating target transition data representing a transition of a value of an index regarding a state of a target storage battery based on measurement data regarding the target storage battery; and a step of estimating a timing at which a target event occurs in the target storage battery based on the target transition data and at least one piece of reference transition data representing a reference transition of the value of the index regarding a state of a storage battery in a period from a first time to a second time at which the target event occurs in the storage battery.

Clause 18 An information processing system comprising:

a target storage battery; and a processing circuitry configured to: calculate target transition data representing a transition of a value of an index regarding a state of a target storage battery based on measurement data regarding the target storage battery; and estimate a timing at which a target event occurs in the target storage battery based on the target transition data and at least one piece of reference transition data representing a reference transition of the value of the index regarding a state of a storage battery in a period from a first time to a second time at which the target event occurs in the storage battery.

1. An information processing device comprising: a processing circuitry configured to:
calculate target transition data representing a transition of a value of an index regarding a state of a target storage battery based on measurement data regarding the target storage battery; and
estimate a timing at which a target event occurs in the target storage battery based on the target transition data and at least one piece of reference transition data representing a reference transition of the value of the index regarding a state of a storage battery in a period from a first time to a second time at which the target event occurs in the storage battery.

2. The information processing device according to claim 1, wherein
the target storage battery has a plurality of cells, and
the processing circuitry calculates the value of the index based on a minimum voltage and a maximum voltage among voltages of the plurality of cells in the target storage battery for each of a plurality of third times, and calculates data including the values of the index at the plurality of third times as the target transition data.

3. The information processing device according to claim 1, wherein
the processing circuitry
calculates transition data representing a transition of the value of the index regarding states of a plurality of storage batteries until the target event occurs in the plurality of storage batteries based on measurement data regarding the plurality of storage batteries in which the target event has occurred;
generates at least one cluster each including one or more pieces of the transition data by clustering a plurality of pieces of the transition data calculated for the plurality of storage batteries; and
generates the reference transition data for each of the clusters based on the one or more pieces of the transition data included in the cluster.

4. The information processing device according to claim 1, wherein
the processing circuitry:
maps the target transition data and a plurality of pieces of the reference transition data in a space defined by time and the index;
selects one piece of the reference transition data based on a distance between the target transition data and the plurality of pieces of the reference transition data by moving at least one of the target transition data or the plurality of pieces of the reference transition data in a time direction, and aligns the one piece of the reference transition data with the target transition data;
calculates a distance in the time direction from an end of the target transition data to an end of the one piece of the reference transition data; and
estimates the timing at which the target event occurs by adding a time corresponding to the calculated distance in the time direction to a time indicated by data at the end of the target transition data.

5. The information processing device according to claim 1, wherein
the processing circuitry:
maps the target transition data and a plurality of pieces of the reference transition data in a space defined by time and the index;
selects two or more pieces of the reference transition data for the target transition data based on a distance between the target transition data and the plurality of pieces of the reference transition data by moving at least one of the target transition data or the plurality of pieces of the reference transition data in a time direction, and aligns the selected two or more pieces of the reference transition data with the target transition data;
calculates a plurality of distances in the time direction from an end of the target transition data to ends of the two or more pieces of the reference transition data; and
estimates the timing at which the target event occurs based on times corresponding to the calculated plurality of distances in the time direction, a ratio between the distances associated with the respective two or more pieces of the reference transition data, and a time indicated by data at the end of the target transition data.

6. The information processing device according to claim 1, wherein
attribute information indicating a temporal change or an accumulated value of at least one of temperature, a current value, a voltage value, a power value, and an SoC is associated with each of a plurality of pieces of the reference transition data, and
the processing circuitry:
calculates attribute information indicating a temporal change or an accumulated value of at least one of temperature, a current value, a voltage value, a power value, and an SoC based on the measurement data regarding the target storage battery; and
selects at least one piece of the reference transition data based on the calculated attribute information and a plurality of pieces of the attribute information associated with the plurality of pieces of the reference transition data, and estimates the timing at which the target event occurs based on the selected reference transition data and the target transition data.

7. The information processing device according to claim 1, wherein
the processing circuitry
acquires information indicating a timing at which the target event occurred in the target storage battery, and
when a difference between the timing indicated by the acquired information and the estimated timing at which the target event occurs satisfies a condition, generates the reference transition data based on transition data of the value of the index of the target storage battery until the target event occurs.

8. The information processing device according to claim 1, wherein
the target event is stopping of operation, and
the timing at which the target event occurs in the target storage battery is a time at which operation of the target storage battery stops.

9. The information processing device according to claim 8, wherein
the time at which operation of the target storage battery stops is a date on which operation of the target storage battery stops.

10. The information processing device according to claim 1, wherein
the target storage battery has a plurality of cells, and
the processing circuitry calculates a first SoH based on the measurement data of the target storage battery, calculates a second SoH based on a minimum voltage and a maximum voltage among voltages of the plurality of cells in the target storage battery, and calculates the value of the index using a ratio between the second SoH and the first SoH.

11. The information processing device according to claim 4, wherein
the processing circuitry selects the reference transition data having a similarity according to the distance that is equal to or higher than a threshold and having the highest similarity, and when the reference transition data having the similarity equal to or higher than the threshold does not exist, estimates that the timing at which the target event occurs is after a time obtained by adding a length of the period from the first time to the second time to a time indicated by data at the end of the target transition data.

12. The information processing device according to claim 4, wherein
the processing circuitry selects the reference transition data having a similarity according to the distance that is equal to or higher than a threshold and having the highest similarity,
the processing circuitry estimates the timing at which the target event occurs for a plurality of the target storage batteries, and
when there is a target storage battery for which the reference transition data having the similarity equal to or higher than the threshold does not exist, the processing circuitry sets, as the timing at which the target event occurs, a time obtained by adding a time period until a latest timing among timings estimated for one or more of the target storage batteries for which the reference transition data having the similarity equal to or higher than the threshold exists, to a time indicated by data at the end of the target transition data of the target storage battery for which the reference transition data having the similarity equal to or higher than the threshold does not exist.

13. The information processing device according to claim 1, wherein
the processing circuitry
calculates a similarity based on a distance between the target transition data and a plurality of pieces of the reference transition data, selects the reference transition data having the largest similarity, and
aligns the reference transition data with the target transition data at a position where the similarity becomes largest.

14. The information processing device according to claim 5, wherein
the processing circuitry
calculates a similarity based on a distance between the target transition data and a plurality of pieces of the reference transition data, selects two or more pieces of the reference transition data having the largest similarity, and
aligns each of the two or more pieces of the reference transition data with the target transition data at a position where the similarity becomes largest.

15. The information processing device according to claim 1, wherein
the processing circuitry:
maps the target transition data and the reference transition data in a space defined by time and the index;
aligns the reference transition data with the target transition data at a position where a similarity according to a distance between the target transition data and the reference transition data becomes highest or becomes equal to or higher than a threshold by moving at least one of the target transition data or the reference transition data in a time direction;
calculates a distance in the time direction from an end of the target transition data to an end of one piece of the reference transition data; and
estimates the timing at which the target event occurs by adding a time corresponding to the calculated distance in the time direction to a time indicated by data at the end of the target transition data.

16. An information processing method comprising:
calculating target transition data representing a transition of a value of an index regarding a state of a target storage battery based on measurement data regarding the target storage battery; and
estimating a timing at which a target event occurs in the target storage battery based on the target transition data and at least one piece of reference transition data representing a reference transition of the value of the index regarding a state of a storage battery in a period from a first time to a second time at which the target event occurs in the storage battery.

17. A non-transitory computer readable medium having a computer program which causes a computer to execute processes comprising:
calculating target transition data representing a transition of a value of an index regarding a state of a target storage battery based on measurement data regarding the target storage battery; and
estimating a timing at which a target event occurs in the target storage battery based on the target transition data and at least one piece of reference transition data representing a reference transition of the value of the index regarding a state of a storage battery in a period from a first time to a second time at which the target event occurs in the storage battery.

18. An information processing system comprising:
a target storage battery; and
a processing circuitry configured to: calculate target transition data representing a transition of a value of an index regarding a state of a target storage battery based on measurement data regarding the target storage battery; and estimate a timing at which a target event occurs in the target storage battery based on the target transition data and at least one piece of reference transition data representing a reference transition of the value of the index regarding a state of a storage battery in a period from a first time to a second time at which the target event occurs in the storage battery.
